(19) United States
(12) Patent Application Publication
(10) Pub. No.: US 2025/0292826 A1
(43) Pub. Date: Sep. 18, 2025

(54) SEMICONDUCTOR STORAGE DEVICE

(71) Applicant: Kioxia Corporation, Tokyo (JP)

(72) Inventors: Takeshi AOKI, Ebina Kanagawa (JP); Tsuneo INABA, Kamakura Kanagawa (JP); Masaharu WADA, Yokohama Kanagawa (JP)

(73) Assignee: Kioxia Corporation, Tokyo (JP)

(21) Appl. No.: 18/828,142

(22) Filed: Sep. 9, 2024

(30) Foreign Application Priority Data
Mar. 15, 2024 (JP) 2024-041553

(51) Int. Cl. G11C 11/4096; G11C 11/4091; G11C 11/4094

(52) U.S. Cl. CPC G11C 11/4096; G11C 11/4091; G11C 11/4094

(57) ABSTRACT

A memory includes a first data-line and a first control-line for writing and a second data-line and a second control-line for reading. A memory cell includes a first transistor connected to the first control-line at a gate and connected to the first data-line, a second transistor connected to the second control-line at a gate and connected to the second data-line, and a third transistor connected to the first transistor at a gate and connected to the second transistor. A detector is connected to the first and second data-lines. In writing or reading, the controller activates the second control-line, the detector detects first data based on a voltage of the second data-line, and thereafter the controller activates the first control-line. After reception of a write command, the detector transmits second data from outside to the gate of the third transistor when latching the second data.

### CROSS REFERENCE TO RELATED APPLICATIONS

This application is based upon and claims the benefit of priority from the prior Japanese Patent Application No. 2024-041553, filed on Mar. 15, 2024, the entire contents of which are incorporated herein by reference.

### FIELD

The embodiments of the present invention relate to a semiconductor storage device.

### BACKGROUND

In a gain cell memory, data is read by amplifying charges stored in a sense node by a transistor. In such a gain cell memory, reduction in power consumption is desired.

### BRIEF DESCRIPTION OF THE DRAWINGS

FIG. 1 is a circuit diagram illustrating a configuration example of a memory cell of a gain cell memory according to a first embodiment;

FIG. 2 is a block diagram illustrating a configuration example of the gain cell memory according to the first embodiment;

FIG. 3 is a state transition diagram illustrating an example in a case where the gain cell memory is caused to operate in a DRAM mode;

FIG. 4 is a timing chart illustrating an example in a case where the gain cell memory is caused to operate in the DRAM mode;

FIG. 5 is a diagram illustrating a state of a sense amplifier in the DRAM mode;

FIG. 6 is a diagram illustrating a state of the sense amplifier in the DRAM mode;

FIG. 7 is a diagram illustrating a state of the sense amplifier in the DRAM mode;

FIG. 8 is a diagram illustrating a state of the sense amplifier in the DRAM mode;

FIG. 9 is a state transition diagram illustrating an example in a case where the gain cell memory is caused to operate in a first gain cell mode;

FIG. 10 is a timing chart illustrating an example in a case where the gain cell memory is caused to operate in the first gain cell mode;

FIG. 11 is a diagram illustrating a state of a sense amplifier in the first gain cell mode;

FIG. 12 is a diagram illustrating a state of the sense amplifier in the first gain cell mode;

FIG. 13 is a diagram illustrating a state of the sense amplifier in the first gain cell mode;

FIG. 14 is a timing chart illustrating an example in a case where the gain cell memory is caused to operate in a second gain cell mode;

FIG. 15 is a diagram illustrating a state of a sense amplifier in the second gain cell mode;

FIG. 16 is a diagram illustrating a state of the sense amplifier in the second gain cell mode;

FIG. 17 is a timing chart illustrating an example of random access in the first gain cell mode;

FIG. 18 is a timing chart illustrating an example of page access in the first gain cell mode;

FIG. 19 is a timing chart illustrating an example of random access in the second gain cell mode;

FIG. 20 is a timing chart illustrating an example of page access in the second gain cell mode;

FIG. 21 is a state transition diagram illustrating operations of a gain cell memory according to a second embodiment;

FIG. 22 is a timing chart illustrating operations of a gain cell memory according to a third embodiment;

FIG. 23 is a timing chart illustrating operations of the gain cell memory according to the third embodiment;

FIG. 24 is a timing chart illustrating operations of a gain cell memory according to a fourth embodiment; and

FIG. 25 is a timing chart illustrating operations of the gain cell memory according to the fourth embodiment.

### DETAILED DESCRIPTION

In general, according to the embodiment, a semiconductor storage device comprises: a first data line and a first control line used for data writing; and a second data line and a second control line used for data reading. A plurality of memory cells each include a first transistor connected to the first control line at a gate and connected to the first data line at one end, a second transistor connected to the second control line at a gate and connected to the second data line at one end, and a third transistor that includes a gate connected to the other end of the first transistor and retaining data from the first data line and one end connected to the other end of the second transistor, the third transistor having a conducting state depending on the data. A detection circuit is connected to the first and second data lines and configured to latch data from outside and apply a voltage depending on the latched data to the first data line or to detect data based on a voltage of the second data line. A controller is configured to control the first control line and the second control line. In data writing or data reading, after the controller activates the second control line and the detection circuit detects first data based on the voltage of the second data line, the controller activates the first control line, and the detection circuit transmits the first data to the gate of the third transistor. After reception of a write command instructing writing, the detection circuit transmits second data from outside to the gate of the third transistor when latching the second data. Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First Embodiment

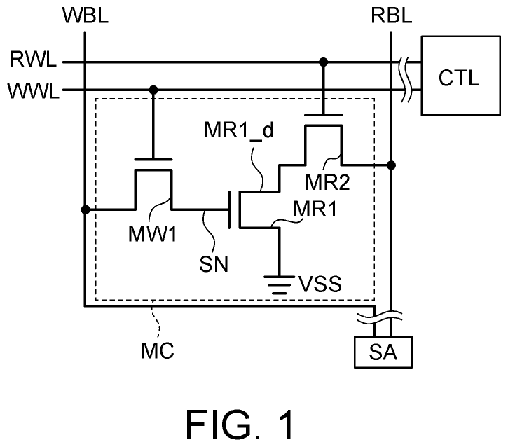

FIG. 1 is a circuit diagram illustrating a configuration example of a memory cell of a gain cell memory according to a first embodiment. A memory cell MC of the gain cell memory is configured by three transistors MW1, MR1, and MR2. The transistors MW1, MR1, and MR2 are each configured by an n-OSFET (Oxide Semiconductor Field Effect Transistor), for example.

The gate of the transistor MW1 as a first transistor is connected to a write word line WWL as a first control line. One electrode of the transistor MW1 is connected to a write bit line WBL as a first data line. The other electrode of the transistor MW1 is connected to the gate of the transistor MR1. The one electrode and the other electrode of the transistor MW1 serve as a source electrode or a drain electrode in accordance with the voltage supplied to the transistor MW1. The transistor MW1 connects the write bit line WBL to the gate of the transistor MR1 serving as a sense node SN (hereinafter, also “sense node SN”) under control of the write word line WWL. The transistor MW1 transmits the voltage of the write bit line WBL to the sense node SN in a conducting state. The transistor MW1 retains the voltage of the sense node SN in a non-conducting state. As described above, the transistor MW1 can write the voltage (data) from the write bit line WBL to the sense node SN or can retain the voltage (data) written to the sense node SN.

The gate of the transistor MR1 as a third transistor is connected to the other electrode of the transistor MW1 and serves as the sense node SN. One electrode (source) of the transistor MR1 is connected to a low voltage source VSS. The other electrode (drain) of the transistor MR1 is connected to one electrode of the transistor MR2. The transistor MR1 is placed in a state in accordance with the voltage (i.e., data) of the sense node SN. For example, in a case where the sense node SN is maintained to the high-level volage (e.g., data “1”), the transistor MR1 is placed in a conducting state. In a case where the sense node SN is maintained to the low-level volage (e.g., data “0”), the transistor MR1 is placed in a non-conducting state.

The gate of the transistor MR2 as a second transistor is connected to a read word line RWL as a second control line. One electrode of the transistor MR2 is connected to the drain of the transistor MR1. The other electrode of the transistor MR2 is connected to a read bit line RBL as a second data line. The one electrode and the other electrode of the transistor MR2 can serve as a source electrode or a drain electrode in accordance with the voltage supplied to the transistor MR2. The transistor MR2 connects the read bit line RBL to the drain of the transistor MR1 under control of the read word line RWL. The transistor MR1 is placed in a state (a conducting state or a non-conducting state) depending on the voltage (i.e., data) retained in the sense node SN. When the transistor MR2 connects the read bit line RBL to the transistor MR1 in a conducting state, charges from the read bit line RBL flow to the low voltage source VSS in accordance with the state of the transistor MR1. When the transistor MR1 is in a conducting state, the charges from the read bit line RBL flow to the low voltage source VSS, so that the voltage of the read bit line RBL becomes low. When the transistor MR1 is in a non-conducting state, almost no charge flows from the read bit line RBL to the low voltage source VSS, so that the voltage of the read bit line RBL is kept high. Accordingly, the voltage based on the data retained in the sense node SN is transmitted to the read bit line RBL.

A sense amplifier SA as a detection circuit is connected to the write bit line WBL and the read bit line RBL. The sense amplifier SA latches write data from outside and applies the voltage depending on the write data to the write bit line WBL. Further, the sense amplifier SA detects read data based on the voltage of the read bit line RBL and latches the read data. The read data latched by the sense amplifier SA is transmitted to outside. The sense amplifier SA also precharges the write bit line WBL and the read bit line RBL.

A controller CTL is connected to the write word line WWL and the read word line RWL and controls the voltage of the write word line WWL and the voltage of the read word line RWL.

The write word line WWL and the write bit line WBL are wires used for writing of data. The read word line RWL and the read bit line RBL are wires used for reading of data. As described above, the gain cell memory uses different word lines and different bit lines for data writing and data reading. Accordingly, the gain cell memory allows data in the sense node SN to be read while the data is maintained (non-destructive reading). One memory cell MC is configured by the three transistors MW1, MR1, and MR2, and does not include a capacitor difficult to miniaturize, unlike a DRAM (Dynamic Random Access Memory). Therefore, the gain cell memory is excellent for miniaturization.

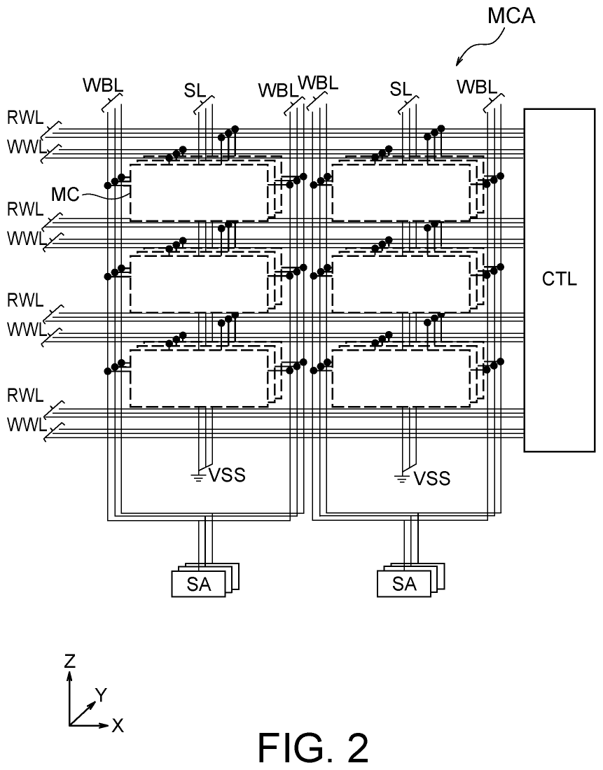

FIG. 2 is a block diagram illustrating a configuration example of a gain cell memory according to the first embodiment. The gain cell memory according to the present embodiment includes a three-dimensional memory cell array in which a plurality of memory cells MC are arranged three-dimensionally. The memory cells MC are arranged in a matrix including a plurality of rows and a plurality of columns. The row is the arrangement of memory cells MC in the X-direction. The column is the arrangement of memory cells MC in the Z-direction. Further, the matrices of memory cells MC are arranged in the Y-direction. Accordingly, a memory cell array MCA is a three-dimensional array in which the memory cells MC are arranged three-dimensionally. The number of rows, the number of columns, and the number of matrices of the memory cells MC are not limited to any specific number.

The write word lines WWL are provided to correspond to the respective rows of memory cells MC. The read word lines RWL are also provided to correspond to the respective rows of memory cells MC.

The write bit lines WBL are provided to correspond to the respective columns of memory cells MC. The read bit lines RBL are also provided to correspond to the respective columns of memory cells MC. The sense amplifiers SA are also provided to correspond to the respective columns of memory cells MC. Further, source lines SL are also provided to correspond to the respective columns of memory cells MC.

Next, operations of the gain cell memory in the present embodiment are described.

### (DRAM Mode: First Mode)

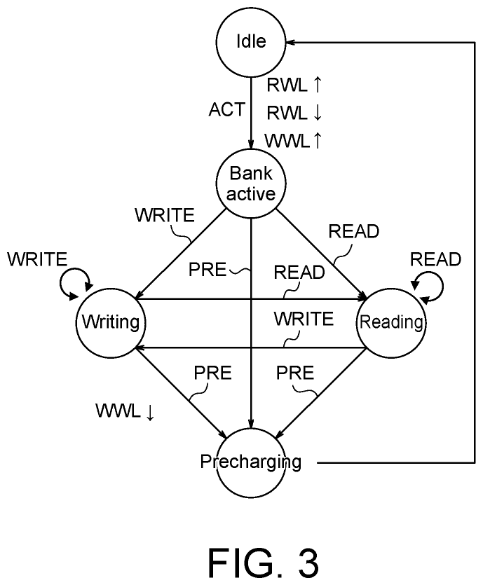

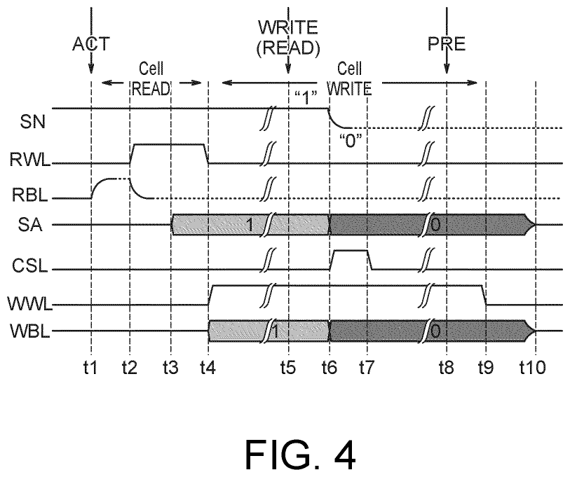

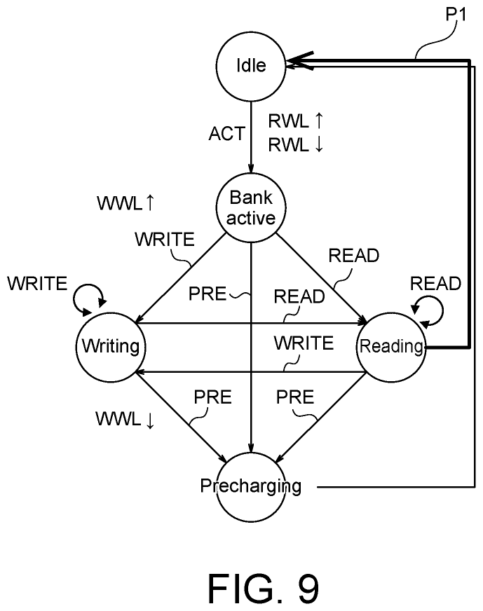

FIG. 3 is a state transition diagram illustrating an example in a case where the gain cell memory is caused to operate in the DRAM mode. In FIG. 3, an arrow next to each command of line (e.g. RWL, WWL) indicates an active state or an inactive state. An upward arrow indicates activation, and a downward arrow indicates deactivation. The same also applies to FIGS. 9, 13, and 21. FIG. 4 is a timing chart illustrating an example in a case where the gain cell memory is caused to operate in the DRAM mode. FIG. 4 illustrates a specific example in which data “1” has been stored in the memory cell MC and data “0” is written to the memory cell MC.

Each memory cell MC of the gain cell memory retains data in an idle state (Idle). The gain cell memory regularly executes an operation of restoring the data in each memory cell MC (refresh). The restore operation will be described later.

The memory cell array MCA is divided into a plurality of banks and operates by placing each bank in an active state (Bank active). At t1 in FIG. 4, when the gain cell memory receives an active command ACT, a bank is selectively placed in the active state. In the active state, the read bit lines RBL of the columns in the selected bank are charged. Next, at t2, the read word line RWL corresponding to a row selected from the rows in the bank is activated. Accordingly, data from the memory cells MC corresponding to the selected row is detected and latched by the sense amplifiers SA of the respective columns at t3 to t4.

At t4, the read word line RWL of the selected row is deactivated, and the write word line WWL of the selected row is activated. Accordingly, the memory cells MC of the selected row enter a state of allowing data to be written thereto. At t4 to t5, the data latched by the sense amplifiers SA (data originally stored in the memory cells MC of the selected row) is returned to the sense nodes SN of the memory cells MC of the selected row via the write bit lines WBL of the respective columns.

Next, at t5, when the gain cell memory receives a write command WRITE or a read command READ, the gain cell memory transitions from the active state (Bank active) to a write state (Writing) or a read state (Reading) in FIG. 3. Here, it is assumed that the write command WRITE is issued at t5 as illustrated in FIG. 4. In this case, the gain cell memory transitions from the active state to the write state.

At t6, when a column selection line CSL is raised, write data is transferred to the sense amplifier SA corresponding to a column selected from the columns and latched. In the example of FIG. 4, data “0” has been transferred as the write data to the sense amplifier SA of the selected column. At this time, since the write word line WWL has been activated, the write data is written to the memory cell MC in the selected row which corresponds to the selected column via the write bit line WBL. In the example of FIG. 4, data “0” is written to the memory cell MC of the selected column in the selected row via the write bit line WBL. Accordingly, the data in the sense node SN is inverted from “1” to “0”. Original data stored in the memory cells MC is written back to the memory cells MC in the selected row which correspond to unselected columns. Further, even for the selected column, in a case where the logic of the write data is the same as the logic of the original data stored in the memory cell MC, the original data stored in the memory cell MC is written without logical inversion.

At t7, the column selection line CSL is caused to fall. At t8, a precharge command PRE is issued. Accordingly, the gain cell memory transitions from the write state to a precharge state (Precharging) in FIG. 3. At this time, the write word line WWL is deactivated at t9. Accordingly, the memory cells MC of the selected row are electrically disconnected from the write bit lines WBL and are each placed in a state where write data is retained in the sense node SN. Further, at t10, the sense amplifiers SA of the plural columns precharge the respective write bit lines WBL to, for example, VDD/2. Thereafter, the write bit lines WBL are disconnected from the sense amplifiers SA. VDD is a voltage of a high voltage source, for example. Accordingly, precharging is finished, and the gain cell memory returns to the idle state.

Meanwhile, at t5, when the gain cell memory receives the read command READ, the gain cell memory transitions from the active state (Bank active) to the read state (Reading) in FIG. 3. In this case, when the column selection line CSL is raised at t6, the sense amplifier SA transmits latched data as read data to outside, although not illustrated. The data latched by the sense amplifiers SA is not inverted and is written back to the memory cells MC of the selected row via the write bit lines WBL as it is. Therefore, in the precharge operation, the data in the sense nodes SN of the memory cells MC of the selected row is not inverted and is maintained as it is. The rest of the operations in reading (at t1 to t5 and at t8 to t10) may be the same as that of corresponding operations in writing.

As described above, in the DRAM mode, when data is written or read, the read word line RWL is activated, and the sense amplifier SA detects the data based on the voltage of the read bit line RBL. Thereafter, in the write operation, the write word line WWL is activated, and at the timing at which the sense amplifier SA latches write data from outside by rising of the column selection line CSL, the sense amplifier SA transmits the write data to the sense node SN of the memory cell MC. The memory cell MC retains the data written to the sense node SN. Meanwhile, in the read operation, the write word line WWL is activated, and at the timing at which the sense amplifier SA outputs read data to outside by rising of the column selection line CSL, the sense amplifier SA returns the read data to the sense node SN of the memory cell MC. The memory cell MC retains the data returned to the sense node SN.

Accordingly, in the DRAM mode, in data reading, the read word line RWL is activated, and the sense amplifier SA detects read data based on the voltage of the read bit line RBL. Thereafter, the write word line WWL is activated, and the sense amplifier SA outputs the read data to outside by rising of the column selection line CSL and returns the same data to the sense node SN of the memory cell MC. The memory cell MC retains the read data returned to the sense node SN.

In a restore operation, the gain cell memory reads data retained in each memory cell MC once, and then writes back the same data. In this case, the gain cell memory transitions from the idle state to the active state in FIG. 3 and, when the precharge command PRE is issued afterwards, transitions directly to the precharge state and returns to the idle state. At this time, the column selection line CSL is not raised. The sense amplifier SA neither outputs the data from the memory cell MC to outside nor takes in data from outside. Therefore, writing of data to the sense amplifier SA and reading of data from the sense amplifier SA are not executed, and data detected by the sense amplifier SA in the active state is written back to the original memory cell MC as it is. That is, the controller CTL activates the write word line WWL, and the sense amplifier SA transmits latched data from the memory cell MC to the sense node SN of the original memory cell MC. Accordingly, data of the memory cell MC is restored (refreshed). It suffices that the restore operation is executed while a plurality of rows are selected in turn.

As illustrated in FIG. 3, in a case where the read command READ is received after the write command WRITE is received, the gain cell memory may transition from the write state (Writing) to the read state (Reading). On the contrary, in a case where the write command WRITE is received after the read command READ is received, the gain cell memory may transition from the read state (Reading) to the write state (Writing).

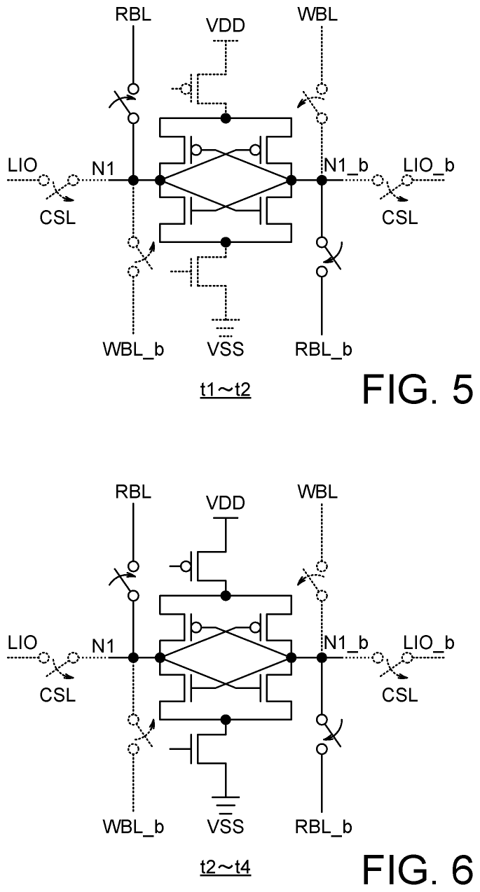

FIGS. 5 to 8 are diagrams illustrating states of a sense amplifier in the DRAM mode. The sense amplifier SA includes a latch circuit configured by two n-MOSFETs and two p-MOSFETs. This latch circuit retains either one of the voltage of the high voltage source VDD and the voltage of the low voltage source VSS in a node N1 depending on data to be latched. For example, in a case where the read bit line RBL has a low-level voltage (data “1”), the node N1 retains a low-level voltage based on the low voltage source VSS. For example, in a case where the read bit line RBL has a high-level voltage (data “0”), the node N1 retains a high-level voltage based on the high voltage source VDD. A node N1_b retains an inverted signal with respect to the node N1. RBL_b indicates an inverted signal of the read bit line RBL. WBL_b indicates an inverted signal of the write bit line WBL. LIO_b indicates an inverted signal of an input/output line LIO.

First, in the active state at t1 to t2, the read bit lines RBL and RBL_b are connected to the sense amplifier SA and charged as illustrated in FIG. 5. This charging is based on a precharge potential. The write bit lines WBL and WBL_b are not connected to the sense amplifier SA.

At t2 to t4, as illustrated in FIG. 6, data from the memory cell MC is detected and latched by the sense amplifier SA via the read bit line RBL.

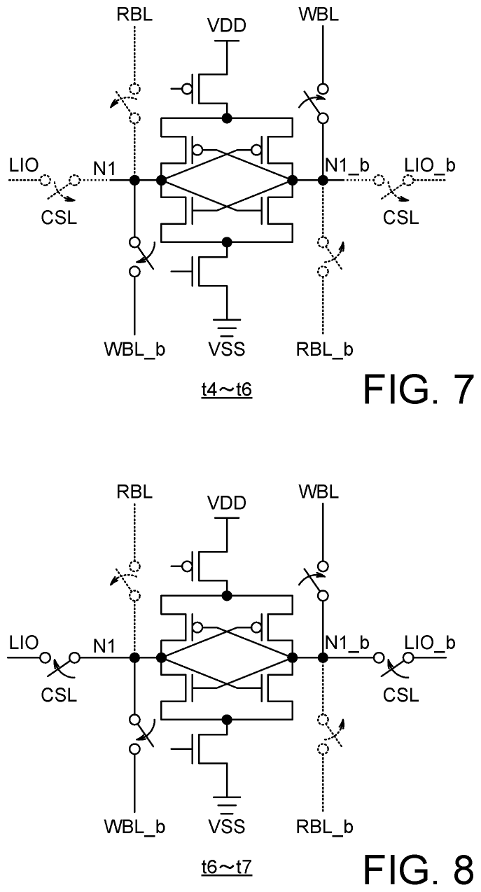

At t4 to t6, as illustrated in FIG. 7, the gain cell memory enters the write state, and the write bit lines RBL and RBL_b are connected to the sense amplifier SA. Accordingly, the data latched by the sense amplifier SA is writable to the memory cell MC. After the read word line RWL is deactivated, the read bit lines RBL and RBL_b are disconnected from the sense amplifier SA.

At t6 to t7, as illustrated in FIG. 8, the column selection line CSL is activated, and the input/output lines LIO and LIO_b are connected to the nodes N1 and N1_b, respectively. Accordingly, write data (data “0”) from outside is latched in the nodes N1 and N1_b and is transmitted to the sense node SN of the memory cell MC via the write bit line WBL.

As described above, the sense amplifier SA can detect data stored in the memory cell MC and output it as read data to outside, or can latch write data from outside and write the write data to the memory cell MC.

In the DRAM mode, when the gain cell memory enters the active state, the read word line RWL is activated once, the sense amplifier SA detects data based on the voltage of the read bit line RBL, and the write word line WWL is then activated before the write command WRITE or the read command READ is received.

In a case where the gain cell memory enters the active state and thereafter the write command WRITE is received, the sense amplifier SA transmits write data from outside to the sense node SN of the memory cell MC at the timing of latching the write data.

In a case where the read command READ is received, the sense amplifier SA outputs latched data to outside.

In the DRAM mode, the gain cell memory can make random access to any memory cell MC in a block of the memory cell array MCA at high speed. Since in the gain cell memory, word lines and bit lines are each divided for writing and reading, the gain cell memory can operate in the identical manner to that of the DRAM. Meanwhile, in the DRAM mode, the gain cell memory activates the write word line WWL every time the gain cell memory enters the active state, irrespective of whether the write command WRITE has been issued. Therefore, in a case where a read operation is repeated, power consumption is increased. Further, in the DRAM mode, since the gain cell memory activates the write word line WWL every time the gain cell memory enters the active state, precharging is required even in the read operation. Therefore, also in a case where the read operation is repeated, power consumption is increased.

### (First Gain Cell Mode: First Sub-Mode in Second Mode)

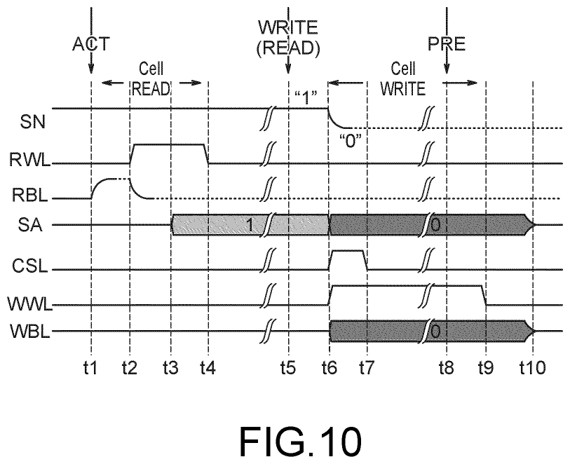

FIG. 9 is a state transition diagram illustrating an example in a case where the gain cell memory is caused to operate in a first gain cell mode. FIG. 10 is a timing chart illustrating an example in a case where the gain cell memory is caused to operate in the first gain cell mode. FIG. 10 illustrates a specific example in which data “1” has been stored in the memory cell MC and data “0” is written to the memory cell MC.

In the first gain cell mode, when the gain cell memory transitions from the idle state to the active state, the write word line WWL is not activated. The write word line WWL is activated after issuing the write command WRITE. For example, as illustrated in FIG. 10, the write word line WWL is activated at the timing of activating the column selection line CSL.

Further, in the first gain cell mode, a path P1 in which the gain cell memory transitions directly from the read state (Reading) to the idle state (Idle) without precharging is set as illustrated in FIG. 9. The gain cell memory allows non-destructive reading as described above, and it is not always necessary to write back original data to the memory cell MC in a read operation. Therefore, in a case where restoring is not necessary, the gain cell memory may transition directly to the idle state after the read operation as illustrated by the path P1.

In FIG. 10, the operations at t1 to t4 may be the same as the operations at t1 to t4 in FIG. 4. However, the write word line WWL is not activated at t4 in the first gain cell mode. Further, data latched by the sense amplifier SA is not transmitted to the write bit line WBL.

At t6, the controller CTL raises the column selection line CSL. Accordingly, write data is transferred to the sense amplifier SA corresponding to a column selected from a plurality of columns and latched. In the example of FIG. 10, data “0” as the write data is transferred to the sense amplifier SA of the selected column. The controller CTL activates the write word line WWL of a selected row at the same timing as the rising of the column selection line CSL. In addition, the write bit lines WBL and WBL_b are connected to the sense amplifier SA. Accordingly, the write data is written to the memory cell MC in the selected row which corresponds to the selected column via the write bit line WBL. In the example of FIG. 10, data “0” is written to the memory cell MC of the selected column in the selected row via the write bit line WBL. Consequently, the data in the sense node SN is inverted from “1” to “0”. Original data stored in the memory cells MC is written back to the memory cells MC in the selected row which correspond to unselected columns. Further, even for the selected column, in a case where the logic of the write data is the same as the logic of the original data stored in the memory cell MC, the original data stored in the memory cells MC is written without logical inversion.

Thereafter, the operations at t7 to t10 in FIG. 10 may be the same as the operations at t7 to t10 in FIG. 4.

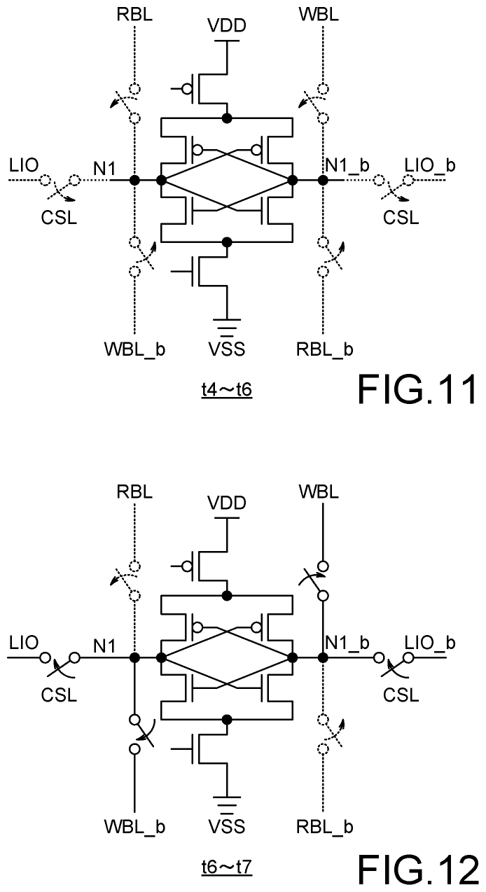

FIGS. 11 and 12 are diagrams illustrating states of a sense amplifier in the first gain cell mode. The states of the sense amplifier SA at t1 to t4 are the same as the states described with reference to FIGS. 5 and 6.

At t4 to t6, the sense amplifier SA illustrated in FIG. 11 retains data read from the memory cell MC.

At t6 to t7, as illustrated in FIG. 12, the column selection line CSL is activated, and the input/output lines LIO and LIO_b are connected to the nodes N1 and N1_b, respectively. Accordingly, write data (data “0”) from outside is latched in the nodes N1 and N1_b. At the same timing as the rising of the column selection line CSL, the write word line WWL is activated. Accordingly, the write data from outside is transmitted to the nodes N1 and N1_b and is also transmitted to the sense node SN of the memory cell MC via the write bit line WBL.

As described above, the sense amplifier SA can detect data stored in the memory cell MC and output it as read data to outside, or can latch write data from outside and write the write data to the memory cell MC.

As described above, in the first gain cell mode, when the gain cell memory enters the active state, the read word line RWL is activated once, and the sense amplifier SA detects read data based on the voltage of the read bit line RBL. At this time, the write word line WWL is kept inactive.

The gain cell memory enters the active state, and thereafter activates the write word line WWL when receiving the write command WRITE. The sense amplifier SA latches write data from outside by rising of the column selection line CSL, and transmits the latched data to the sense node SN of the memory cell MC at the timing of activating the write word line WWL. Since the activation timing of the column selection line CSL and the activation timing of the write word line WWL are substantially the same as each other in the first gain cell mode, the sense amplifier SA transmits the write data from outside to the sense node SN of the memory cell MC at the timing at which it latches the write data.

In a case where the read command READ is received, the write word line WWL is kept inactive, and the sense amplifier SA outputs read data to outside at the timing of activating the column selection line CSL. Since the gain cell memory allows non-destructive reading as described above, the gain cell memory transitions directly to the idle state after a read operation in the first gain cell mode.

### (Second Gain Cell Mode: Second Sub-Mode in Second Mode)

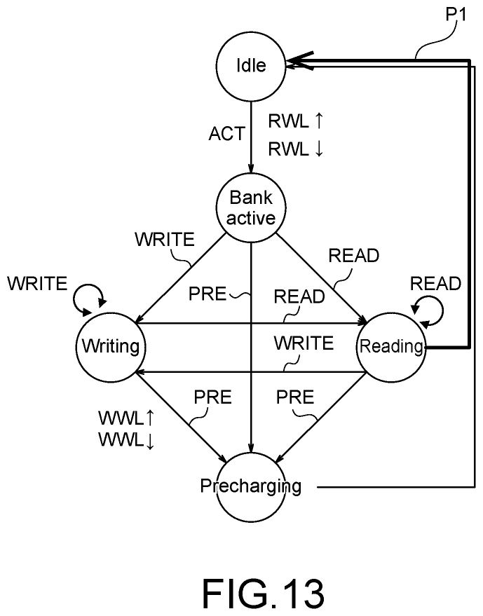

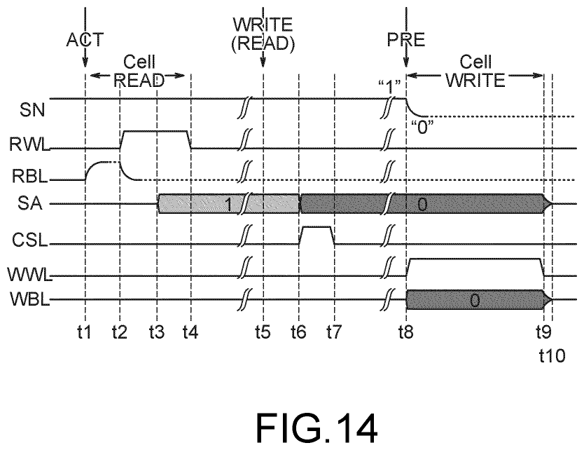

FIG. 13 is a state transition diagram illustrating an example in a case where the gain cell memory is caused to operate in a second gain cell mode. FIG. 14 is a timing chart illustrating an example in a case where the gain cell memory is caused to operate in the second gain cell mode. FIG. 14 illustrates a specific example in which data “1” has been stored in the memory cell MC and data “0” is written to the memory cell MC.

The second gain cell mode is the same as the first gain cell mode in that the write word line WWL is activated after issuing the write command WRITE. However, in the second gain cell mode, the write word line WWL is activated at the timing at which the precharge command PRE is received after activation of the column selection line CSL, as illustrated in FIG. 14, for example.

Further, also in the second gain cell mode, the path P1 in which the gain cell memory transitions directly from the read state to the idle state without precharging is set as illustrated in FIG. 13. This is because the gain cell memory allows non-destructive reading.

In FIG. 14, the operations at t1 to t5 may be the same as the operations at t1 to t5 in FIGS. 10.

At t6 to t7, the controller CTL raises the column selection line CSL. Accordingly, write data is transferred to the sense amplifier SA corresponding to a column selected from a plurality of columns and latched. However, at this time the write word line WWL is not activated yet in the second gain cell mode. After issuing the write command WRITE, the write word line WWL is activated at t8 that is the timing at which the precharge command PRE is received. In addition, the write bit lines WBL and WBL_b are connected to the sense amplifier SA. Accordingly, in the example of FIG. 14, the write word line WWL is activated at the issuance of the precharge command PRE, and the write data latched by the sense amplifier SA is written to the memory cell MC in the selected row which corresponds to the selected column via the write bit line WBL. In the example of FIG.

14, data “0” is written to the memory cell MC of the selected column in the selected row via the write bit line WBL. Consequently, the data in the sense node SN is inverted from “1” to “0”.

Thereafter, the write word line WWL is deactivated at t9, and the write bit line WBL is placed in the precharge state at t10. The write bit lines WBL and WBL_b are disconnected from the sense amplifier SA.

The rest of the operations in the second gain cell mode may be the same as that in the first gain cell mode.

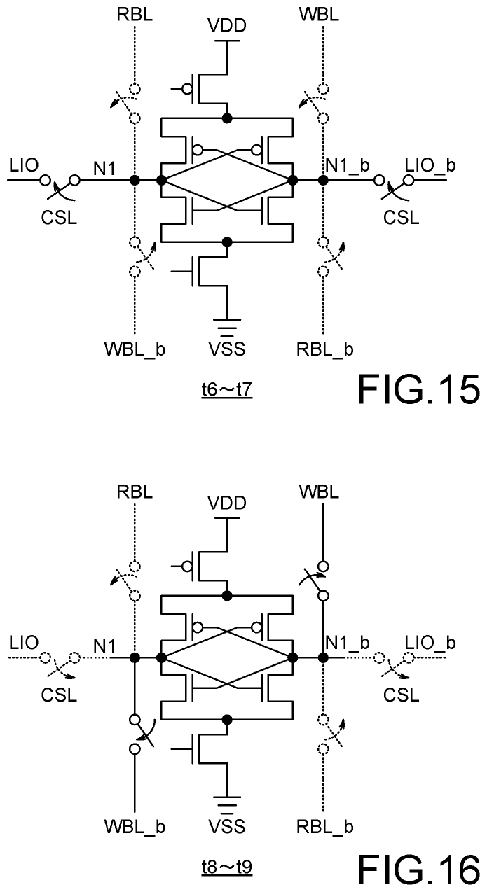

FIGS. 15 and 16 are diagrams illustrating states of a sense amplifier in the second gain cell mode. The states of the sense amplifier SA at t1 to t4 are the same as the states described with reference to FIGS. 5 and 6. The state of the sense amplifier SA at t4 to t6 is the same as the state described with reference to FIGS. 11.

At t6 to t7, as illustrated in FIG. 15, the column selection line CSL is activated, and the input/output lines LIO and LIO_b are connected to the nodes N1 and N1_b, respectively. Accordingly, write data (data “0”) from outside is latched in the nodes N1 and N1_b. At this time, the write word line WWL is not activated yet.

At t8 to t9, as illustrated in FIG. 16, the write word line WWL is activated at the timing of issuing the precharge command PRE. In addition, the write bit lines WBL and WBL_b are connected to the sense amplifier SA. Accordingly, the sense amplifier SA writes the latched write data to the memory cell MC.

As described above, in the second gain cell mode, even when the write command WRITE is received after the gain cell memory enters the active state, the write word line WWL is kept inactive. Further, while the sense amplifier SA latches write data from outside by rising of the column selection line CSL, the write word line WWL is kept inactive also at this time. When the precharge command PRE is issued, the sense amplifier SA transmits the write data to the sense node SN of the memory cell MC.

In a case where the read command READ is received, the write word line WWL is kept inactive, and the sense amplifier SA outputs read data to outside at the timing of activating the column selection line CSL. Since the gain cell memory allows non-destructive reading as described above, the gain cell memory transitions directly to the idle state after a read operation.

The gain cell memory according to the present embodiment can selectively execute any of the DRAM mode, the first gain cell mode, and the second gain cell mode. A mode selection signal instructing which one of the DRAM mode, the first gain cell mode, and the second gain cell mode is to be executed may be set in advance in a program to be executed by the controller CTL. In this case, the gain cell memory repeats execution of the same mode specified by the mode selection signal. Alternatively, when the controller CTL operates, the controller CTL may receive the mode selection signal described above from outside. In this case, the gain cell memory receives the mode selection signal from outside every time it receives the active command ACT, and selects or switches a mode in accordance with this mode selection signal.

In the first and second gain cell modes, the gain cell memory can make random access to any memory cell of the memory cell array MCA or make access by page (page access) (by row or by write word line WWL or read word line RWL) to a selected block of the memory cell array MCA.

### (Random Access in First Gain Cell Mode)

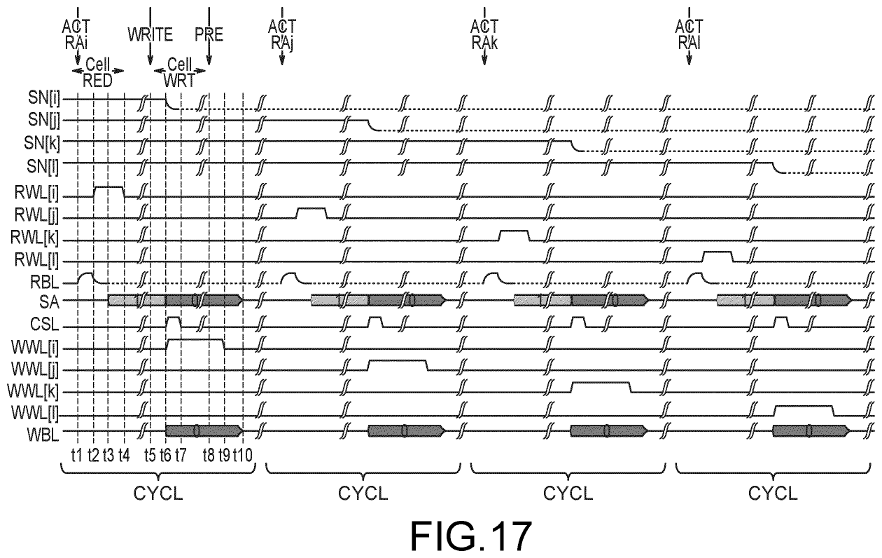

For example, FIG. 17 is a timing chart illustrating an example of random access in the first gain cell mode. In writing by random access, the gain cell memory raises a read word line RWL[i] of a selected row[i] for a selected row address (RA) and places the line in the active state (at t2 to t4). The sense amplifier SA detects and latches data from a selected memory cell MC of a selected column in the memory cells MC of the selected row.

Next, the controller CTL activates the column selection line CSL of the selected column and raises a write word line WWL[i] of the selected row. The sense amplifier SA of the selected column latches write data from outside and applies the write data to a sense node SN[i] of the selected memory cell via the write bit line WBL.

Thereafter, after issuing the precharge command PRE, the write word line WWL[i] is deactivated (at t9), and the write bit line WBL is precharged (at t10).

This write cycle CYCL is selectively executable for any of rows [j] to [l].

In this case, before issuing the precharge command PRE, the write word line WWL is activated, and writing to the memory cell MC is executed. Therefore, it is possible to keep high-speed performance of random access. The read operation is easily understood from the write operation described above and thus explanations thereof are omitted here.

### (Page Access in First Gain Cell Mode)

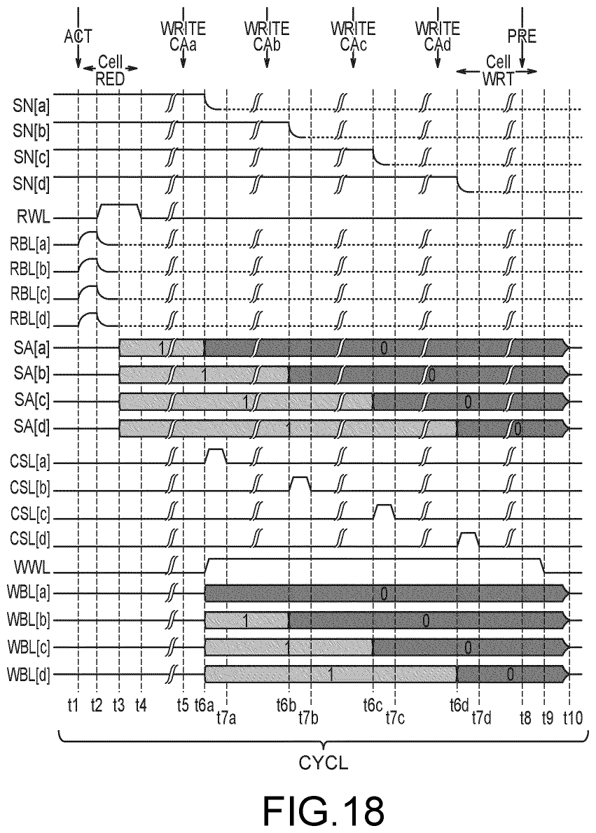

For example, FIG. 18 is a timing chart illustrating an example of page access in the first gain cell mode. In writing by page access, the gain cell memory charges read bit lines RBL[a] to RBL[d] for a plurality of columns [a] to [d] in the row address (RA) and then raises the read word line RWL of a selected row to place the read word line RWL in the active state (at t1 to t4). A plurality of sense amplifiers SA[a] to SA[d] detect and latch data from the memory cells MC of the selected row, respectively.

Next, when receiving the write command WRITE, the controller CTL raises the write word line WWL[i] of the selected row and, in accordance with a column address (CA) received when the write command is received, activates column selection lines CSL[a] to CSL[d] of the respective columns. For example, when the column selection line CSL[a] is activated, the sense amplifier SA[a] of the selected column latches corresponding write data from outside and applies the write data to a sense node SN [a] of a selected memory cell via the write bit line WBL (at t6a to t7a). Similarly, when the column selection lines CSL[b] to CSL[d] are activated in turn, the sense amplifiers SA[b] to SA[d] respectively corresponding thereto of the selected columns latch corresponding write data from outside and apply the write data to sense nodes SN[b] to SN[d] of selected memory cells via the write bit line WBL (at t6b to t7d).

Thereafter, after issuing the precharge command PRE, the write word line WWL is deactivated (at t9), and the write bit line WBL is precharged (at t10).

This write cycle CYCL is selectively executable for any row.

In page access, random access cannot be made to any memory cell MC. However, writing of all data to a selected row (one page data) can be executed by one drive of one write word line WWL. Therefore, page access can be executed with low power consumption. Further, in a read operation, the write command WRITE is not issued because non-destructive reading is possible. Therefore, the write bit line WBL has already been precharged, and therefore a precharge operation is not necessary. Accordingly, the gain cell memory transitions directly to the idle state after the read operation. Consequently, power consumption can further be reduced. In particular, in a case where the read operation is frequently repeated, the effect of reducing power consumption is high.

### (Random Access in Second Gain Cell Mode)

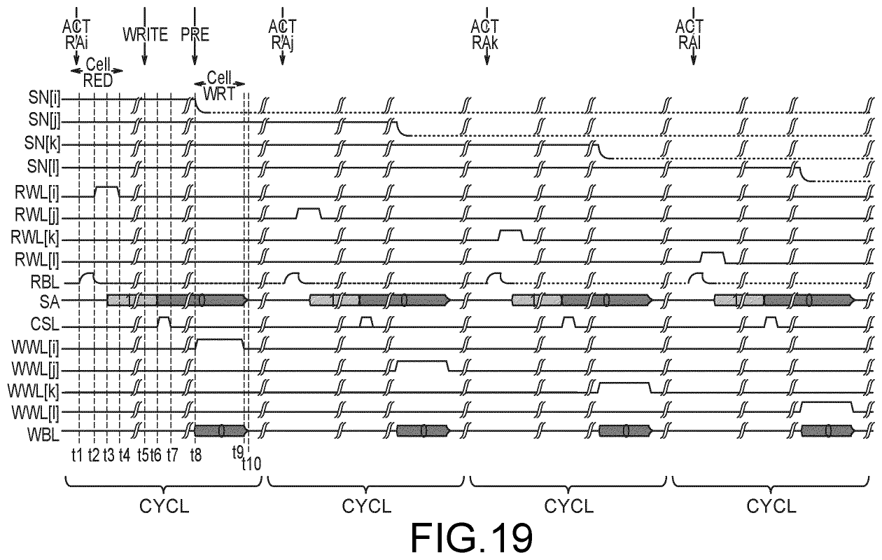

For example, FIG. 19 is a timing chart illustrating an example of random access in the second gain cell mode. A random-access write operation in the second gain cell mode is different from that in the first gain cell mode in rising timings of the write word lines WWL [i] to WWL [l] of selected rows. In the second gain cell mode, the write word lines WWL[i] to WWL[l] of the selected rows are activated when the precharge command PRE is received. The rest of the operations in random access in the second gain cell mode may be the same as that in random access in the first gain cell mode.

In the second gain cell mode, writing from the sense amplifier SA to a sense node is performed after issuing the precharge command PRE, and therefore the write cycle CYCL is relatively longer. For this reason, the DRAM mode or the first gain cell mode is more preferable in terms of high-speed performance of random access.

### (Page Access in Second Gain Cell Mode)

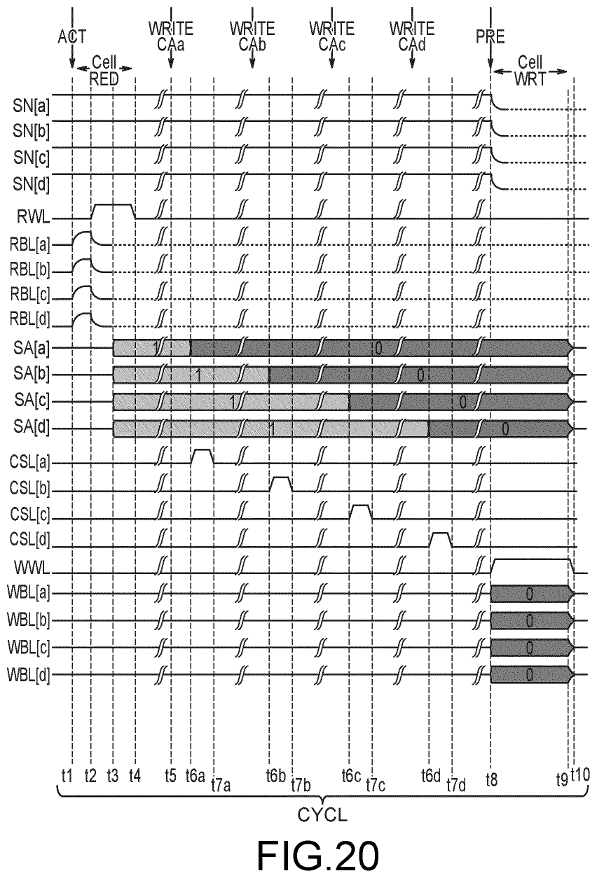

For example, FIG. 20 is a timing chart illustrating an example of page access in the second gain cell mode. In writing by page access, the gain cell memory charges read bit lines RBL[a] to RBL[d] for a plurality of columns [a] to [d] in the row address (RA) and then raises the read word line RWL of a selected row to place the read word line RWL in the active state (at t1 to t4). The sense amplifiers SA[a] to SA[d] detect and latch data from the memory cells MC of the selected row, respectively.

In the second gain cell mode, the write word line WWL of the selected row is activated when the precharge command PRE is received. Accordingly, in page access in the second gain cell mode, when the precharge command PRE is issued and the write word line WWL of the selected row is activated, the data latched by the sense amplifiers SA[a] to SA[d] is written to the sense nodes SN[a] to SN[d] via the write bit lines WBL[a] to WBL[d], respectively (at t8). The rest of the operations in page access in the second gain cell mode may be the same as that in page access in the first gain cell mode.

This write cycle CYCL is also selectively executable for any row.

Page access in the second gain cell mode can obtain identical effects to those of page access in the first gain cell mode. Further, a period during which the write word line WWL is an active state is relatively short in the second gain cell mode. Therefore, the effect of reducing power consumption is high.

In the first or second gain cell mode, the activation timing of the write word line WWL may be any timing between the activation timing of the column selection line CSL and the reception timing of the precharge command PRE.

### Second Embodiment

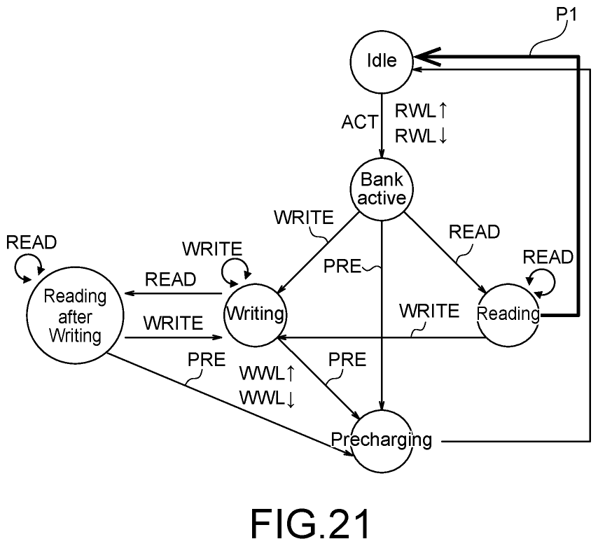

FIG. 21 is a state transition diagram illustrating operations of a gain cell memory according to a second embodiment. The gain cell memory according to the second embodiment can also receive the write command WRITE from the active state and, after a write operation, receive the read command READ for the same page (Reading after Writing). In this case, it suffices to execute precharging after a read operation for the page.

It is also possible to receive the read command READ from the active state and, after a read operation, receive the write command WRITE for the same page. In this case, it suffices that precharging is executed after a write operation for the page.

### Third Embodiment

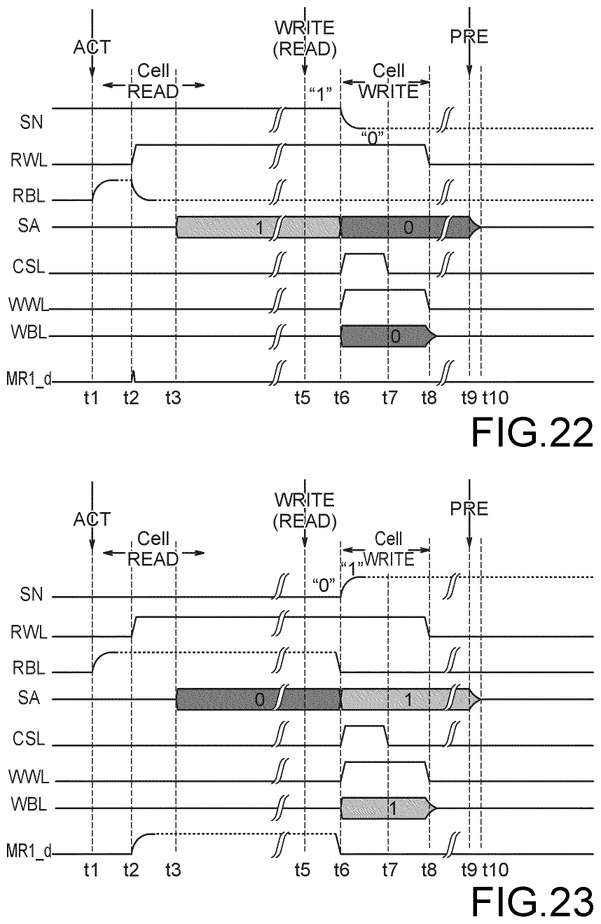

FIGS. 22 and 23 are timing charts illustrating operations of a gain cell memory according to a third embodiment. FIG. 22 illustrates a case where read data is “1” and write data is “0”. FIG. 23 illustrates a case where read data is “0” and write data is “1”.

In the third embodiment, the controller CTL activates the read word line RWL at t2 and then keeps the read word line RWL in an active state until the write word line WWL is deactivated (a write operation ends) at t8. Accordingly, a drain voltage MR1_d of the transistor MR1 does not become a floating state in the write state, and is fixed to the voltage of the read bit line RBL. Consequently, because of a parasitic capacitance present between the drain of the transistor MR1 and the sense node SN, a voltage difference between the data “0” and the data “1” (a sense margin) can be made larger.

The rest of the operations in the third embodiment may be the same as that in the second gain cell mode in the first embodiment. Further, the third embodiment may be applied to the DRAM mode or the first gain cell mode. Accordingly, a voltage difference between the data “0” and the data “1” (a sense margin) in the DRAM mode or the first gain cell mode can also be made larger.

### Fourth Embodiment

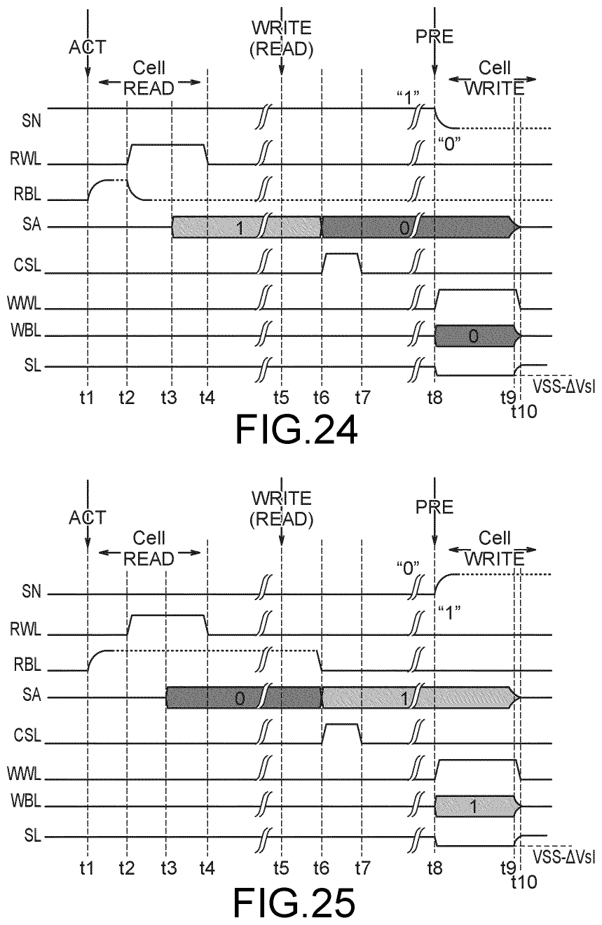

FIGS. 24 and 25 are timing charts illustrating operations of a gain cell memory according to a fourth embodiment. FIG. 24 illustrates a case where read data is “1” and write data is “0”. FIG. 25 illustrates a case where read data is “0” and write data is “1”.

In the fourth embodiment, the voltage of the source line SL is reduced from VSS to the negative side (e.g., VSS-ΔVsl) from activation of the write word line WWL (start of a write operation) at t8 to deactivation of the write word line WWL (end of the write operation) at t9. In the idle state after precharging, the voltage of the source line SL is returned to VSS. In both the write operations of data “0” and data “1”, the voltage of the source line SL is reduced from VSS to the negative side during the activation period of the write word line WWL (during the write operation). This configuration slightly increases the voltage of the sense node SN in the idle state after precharging, without changing the sense margin. Consequently, a source-drain voltage difference Vgs of the transistor MW1 in the idle state is reduced, so that data retention characteristics of the memory cell MC are improved. This improvement enables a cycle of a restore operation to be made longer and leads to reduction of power consumption.

In a case where the memory cell MC retains data “0”, the source-drain voltage difference Vgs of the transistor MW1 is the voltage difference between the sense node SN and the gate of the transistor MW1. In a case where the memory cell MC retains data “1”, the source-drain voltage difference Vgs of the transistor MW1 is the voltage difference between the write bit line WBL and the gate of the transistor MW1.

The rest of the operations in the fourth embodiment may be the same as that in the second gain cell mode of the first embodiment. The fourth embodiment may be also applied to the DRAM mode or the first gain cell mode. Accordingly, data retention characteristics of the DRAM mode or the first gain cell mode can be also improved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a first data line and a first control line used for data writing;
a second data line and a second control line used for data reading;
a plurality of memory cells each including a first transistor connected to the first control line at a gate and connected to the first data line at one end, a second transistor connected to the second control line at a gate and connected to the second data line at one end, and a third transistor that includes a gate connected to the other end of the first transistor and retaining data from the first data line and one end connected to the other end of the second transistor, the third transistor having a conducting state depending on the data;
a detection circuit connected to the first and second data lines and configured to latch data from outside and apply a voltage depending on the latched data to the first data line or to detect data based on a voltage of the second data line; and
a controller configured to control the first control line and the second control line, wherein
in data writing or data reading, after the controller activates the second control line and the detection circuit detects first data based on the voltage of the second data line, the controller activates the first control line, and the detection circuit transmits the first data to the gate of the third transistor, and
after reception of a write command instructing writing, the detection circuit transmits second data from outside to the gate of the third transistor when latching the second data.

2. The device of claim 1, wherein the memory cells are arranged in a plurality of rows and a plurality of columns,
a plurality of the first control lines and a plurality of the second control lines are provided corresponding to the respective rows,
a plurality of the first data lines, a plurality of the second data lines, and a plurality of the detection circuits are provided corresponding to the respective columns,
in data writing or data reading, after the controller activates the second control line corresponding to selected one among the rows, and the detection circuits corresponding to the columns detect the first data based on voltages of the second data lines respectively corresponding thereto, the controller activates the first control line corresponding to the selected row, and the detection circuit transmits the first data to the gate of the third transistor, and
after reception of the write command, the detection circuit corresponding to selected one among the columns transmits the second data from outside to the gate of the third transistor of the memory cell corresponding to the selected row and the selected column when latching the second data.

3. The device of claim 2, wherein the controller deactivates the first control line corresponding to the selected row, and thereafter the detection circuit executes precharging to set the first data line to a predetermined voltage.

4. The device of claim 3, wherein in a case where the write command and a read command are not issued and a precharge command instructing the precharging is issued, the detection circuit transmits the first data to the gate of the third transistor before the precharging.

5. The device of claim 1, wherein the controller activates the second control line in a period during which the first control line is active.

6. The device of claim 1, further comprising a source line connected to the other end of the third transistor, wherein
the controller changes a voltage of the source line in a period during which the first control line is active.

7. A semiconductor storage device comprising:
a first data line and a first control line used for data writing;
a second data line and a second control line used for data reading;
a plurality of memory cells each including a first transistor connected to the first control line at a gate and connected to the first data line at one end, a second transistor connected to the second control line at a gate and connected to the second data line at one end, and a third transistor that includes a gate connected to the other end of the first transistor and retaining data from the first data line and one end connected to the other end of the second transistor, the third transistor having a conducting state depending on the data;
a detection circuit connected to the first and second data lines and configured to latch data from outside and apply a voltage depending on the latched data to the first data line or to detect data based on a voltage of the second data line; and
a controller configured to control the first control line and the second control line, wherein
in data writing or data reading, the controller activates the second control line, and the detection circuit detects first data based on the voltage of the second data line, and
the controller selectively executes either a first mode or a second mode,
the first mode being a mode in which, after detection of the first data, the controller activates the first control line, the detection circuit transmits the first data to the gate of the third transistor, and after reception of a write command instructing writing, the detection circuit transmits second data from outside to the gate of the third transistor when latching the second data, and
the second mode being a mode in which, after detection of the first data, the detection circuit outputs the first data to outside or latches second data from outside, and when the controller activates the first control line, the detection circuit transmits the first or second data to the gate of the third transistor.

8. The device of claim 7, wherein the controller selects the first mode or the second mode based on a mode selection signal selecting the first mode or the second mode.

9. The device of claim 8, wherein the second mode includes at least either one of
a first sub-mode in which at a timing at which the detection circuit outputs the first data to outside or latches the second data from outside, the controller activates the first control line, and
a second sub-mode in which after the detection circuit outputs the first data to outside or latches the second data from outside, the controller activates the first control line at a timing of issuing a precharge command to set the first data line to a predetermined voltage.

10. The device of claim 9, wherein the controller selects the first sub-mode or the second sub-mode based on a mode selection signal selecting the first sub-mode or the second sub-mode.

11. The device of claim 7, wherein, in the first mode, the controller activates the second control line in a period during which the first control line is active.

12. The device of claim 7, further comprising a source line connected to the other end of the third transistor, wherein
the controller changes a voltage of the source line in a period during which the first control line is active.

13. A semiconductor storage device comprising:
a first data line and a first control line used for data writing;
a second data line and a second control line used for data reading;
a plurality of memory cells each including a first transistor connected to the first control line at a gate and connected to the first data line at one end, a second transistor connected to the second control line at a gate and connected to the second data line at one end, and a third transistor that includes a gate connected to the other end of the first transistor and retaining data from the first data line and one end connected to the other end of the second transistor, the third transistor having a conducting state depending on the data;
a detection circuit connected to the first and second data lines and configured to latch data from outside and apply a voltage depending on the latched data to the first data line or to detect data based on a voltage of the second data line; and
a controller configured to control the first control line and the second control line, wherein
in data writing or data reading, the controller activates the second control line, and the detection circuit detects first data based on the voltage of the second data line,
when a read command instructing reading is received, the controller does not activate the first control line, and the detection circuit outputs the first data to outside, and
when a write command instructing writing is received, the detection circuit latches second data from outside, and when the controller activates the first control line, the detection circuit transmits the second data to the gate of the third transistor.

14. The device of claim 13, wherein
the memory cells are arranged in a plurality of rows and a plurality of columns,
a plurality of the first control lines and a plurality of the second control lines are provided corresponding to the respective rows,
a plurality of the first data lines, a plurality of the second data lines, and a plurality of the detection circuits are provided corresponding to the respective columns,
in data writing or data reading, the second control line corresponding to selected one among the rows is activated, and the detection circuits corresponding to the columns detect the first data based on voltages of the second data lines respectively corresponding thereto, and
in a case where the write command is received, the detection circuits latch the second data from outside, and when the controller activates the first control line corresponding to the selected row, the detection circuits transmit the second data to the gates of the third transistors of the memory cells corresponding to the selected row and the columns.

15. The device of claim 14, wherein in a case where the write command is received, after transmission of the second data, the controller deactivates the first control line corresponding to the selected row, and thereafter the detection circuit executes precharging to set the first data line to a predetermined voltage.

16. The device of claim 15, wherein in a case where the write command and the read command are not issued and a precharge command instructing the precharging is issued, the controller activates the first control line, and the detection circuit transmits the first data to the gate of the third transistor before the precharging.

17. The device of claim 13, comprising at least either one of
a first sub-mode in which at a timing at which the detection circuit outputs the first data to outside or latches the second data from outside, the controller activates the first control line, and
a second sub-mode in which after the detection circuit outputs the first data to outside or latches the second data from outside, the controller activates the first control line at a timing of issuing a precharge command to set the first data line to a predetermined voltage.

18. The device of claim 14, comprising at least either one of
a first sub-mode in which at a timing at which the detection circuit outputs the first data to outside or latches the second data from outside, the controller activates the first control line, and
a second sub-mode in which after the detection circuit outputs the first data to outside or latches the second data from outside, the controller activates the first control line at a timing of issuing a precharge command to set the first data line to a predetermined voltage.

19. The device of claim 17, wherein the controller selects the first sub-mode or the second sub-mode based on a mode selection signal selecting the first sub-mode or the second sub-mode.

20. The device of claim 13, wherein the controller activates the first control line at any timing between a timing at which the detection circuit outputs the first data to outside or latches the second data from outside and a timing of issuing a precharge command to set the first data line to a predetermined voltage.

21. The device of claim 13, wherein the controller activates the second control line in a period during which the first control line is active.

22. The device of claim 13, further comprising a source line connected to the other end of the third transistor, wherein
the controller changes a voltage of the source line in a period during which the first control line is active.
